(19) United States
(12) Patent Application Publication
(10) Pub. No.: US 2011/0008972 A1
(43) Pub. Date: Jan. 13, 2011

(54) METHODS FOR FORMING AN ALD SIO2 FILM

(76) Inventors: Daniel Damjanovic, Meridian, ID (US); Shyam Surthi, Boise, ID (US)

Correspondence Address: DICKSTEIN SHAPIRO LLP, 1825 EYE STREET NW, Washington, DC, 20006-5403, US

(21) Appl. No.: 12/501,841

(22) Filed: Jul. 13, 2009

(51) Int. Cl. H01L 21/316; B08B 5/00

(52) U.S. Cl. 438/787; 137/15.04; 257/E21.278

(57) ABSTRACT

Methods of forming a silicon dioxide material by an atomic layer deposition process and methods of preparing a substrate for the formation of a silicon dioxide material by an atomic layer deposition process are provided. In at least one such method, prior to forming the silicon oxide material, at least one pump and exhaust cycle is conducted. Such a pump and exhaust cycle includes at least one pump step, whereby a purge gas is pumped into the reaction chamber, and at least one exhaust step, whereby the purge gas is exhausted from a reaction chamber. The silicon oxide material is then formed on a surface of the substrate.

### FIELD OF THE INVENTION

Embodiments of the invention relate generally to methods of forming silicon dioxide by atomic layer deposition.

### BACKGROUND

As the sizes of electronic devices shrink, it is increasingly important to have techniques that enable the deposition of very thin layers of materials without deformation of the intended structures. Atomic layer deposition (ALD) is one technique that can be used. During an ALD process, reactant gases are sequentially introduced (e.g., pumped) into a reaction chamber containing a substrate.

The formation of silicon dioxide by ALD is a process that is known in the art. In forming silicon dioxide by ALD, a silicon precursor may be pumped into the chamber followed by an oxidizing component. For certain ALD processes, a substrate is maintained at a high temperature which may cause deformation in a resist material and the resulting structures.

A lower temperature ALD process for forming silicon dioxide using hexachlorodisilane (HCD) as a precursor and water as an oxidizing component has been developed. It has been found that maintaining the substrate at lower temperatures can increase growth rates and, therefore, throughput. However, the lower temperatures can result in increased defect formation. What is needed is a process for forming silicon dioxide using a low temperature ALD process that results in fewer defects in the silicon dioxide.

### BRIEF DESCRIPTION OF THE DRAWINGS

FIG. 1 is a block diagram of an apparatus for performing atomic layer deposition.

FIG. 2 is a flowchart of a deposition process according to an embodiment described herein.

### DETAILED DESCRIPTION

In the following detailed description, reference is made to the accompanying drawings which form a part hereof, and in which is shown by way of illustration specific embodiments by which the invention may be practiced. It should be understood that like reference numerals represent like elements throughout the drawings. These example embodiments are described in sufficient detail to enable those skilled in the art to practice them. It is to be understood that other embodiments may be utilized, and that structural and logical changes may be made.

The terms “wafer” and “substrate” are to be understood as including all forms of semiconductor wafers and substrates including silicon, silicon-on-insulator (SOI), silicon-on-sapphire (SOS), doped and undoped semiconductors, epitaxial layers of silicon supported by a base semiconductor foundation, and other semiconductor structures. Furthermore, when reference is made to a “wafer” or “substrate” in the following description, previous process steps may have been utilized to form regions or junctions in the base semiconductor structure or foundation. In addition, the semiconductor need not be silicon-based, but could be based on other semiconductors, for example, silicon-germanium, germanium, or gallium arsenide.

A process for forming a silicon dioxide (SiO₂) film by an atomic layer deposition (ALD) process is presented. The process includes a method for preparing a substrate on which the silicon dioxide film is to be formed. The disclosed process is suitable for forming a silicon dioxide film while maintaining the substrate at low temperatures (e.g., at or below about seventy five degrees Celsius (75° C.)).

When a silicon dioxide film is formed, for example, using hexachlorodisilane (HCD) as a precursor and water as the oxidizing component, the rate of formation of the silicon dioxide film increases as the processing temperature (i.e., the temperature at which the substrate is maintained during processing) decreases when the thermal desorption of the process occurs at higher temperatures (e.g., greater than about 100° C.). One such method for the formation of silicon dioxide at lower processing temperatures is described in U.S. patent application Ser. No. 11/559,491 filed on Nov. 14, 2006. When a silicon dioxide film is to be formed on a photoresist material, lower processing temperatures have also been found to reduce the amount of the resist deformation as compared to higher processing temperatures (e.g., above about one hundred degrees Celsius (100° C.). With reduced resist deformation, patterned features can be better maintained.

As the processing temperature and the standby temperature (i.e., the temperature of the substrate prior to the actual formation) decreases below about one hundred degrees Celsius (100° C.), the number of defects in the formed silicon dioxide film significantly increase. The lower the temperature, the greater the number of defects.

In the process disclosed herein, a pre-deposition pump and exhaust process is performed, which can serve to reduce the number of defects while enabling low processing and standby temperatures.

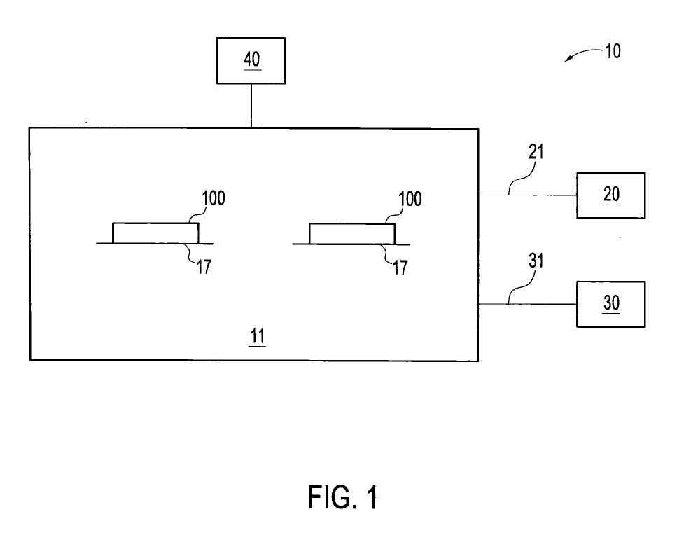

FIG. 1 is a block diagram of an apparatus 10 for performing an ALD process. The apparatus 10 comprises a reaction chamber 11 having one or more susceptors 17 upon which a substrate 100 may be placed. The apparatus 10 may be configured to process a single substrate 100 or it may be configured to process a plurality of substrates 100 simultaneously, as shown in FIG. 1.

The apparatus 10 includes an input component 20. Materials, such as precursors, purge gases, and carrier gases, may be pumped from the input component 20 into the reaction chamber 11. The apparatus 10 also includes an exhaust component 30 through which materials can be removed (e.g., exhausted) from the reaction chamber 11. The input component 20 and exhaust component 30 can include one or more lines 21, 31 connected directly or indirectly to the reaction chamber 11, such as supply and bypass lines. Additionally, the apparatus 10 includes a control component 40, for controlling the pressure and temperature of the reaction chamber and, if desired, the temperature inside the susceptors 17, and therefore the temperature of the substrate(s) 100.

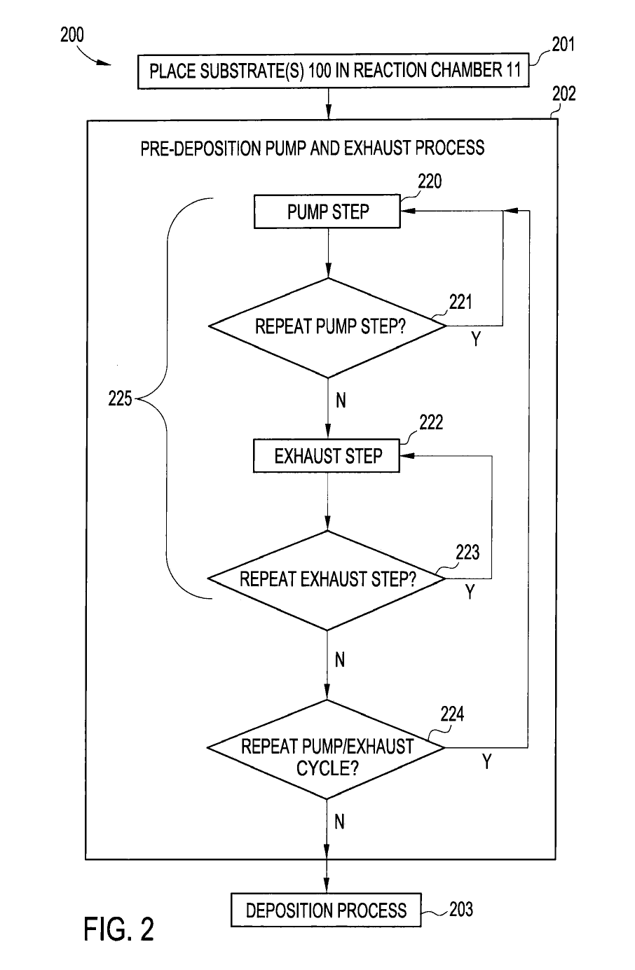

FIG. 2 is a flowchart depicting a method 200 of forming a silicon dioxide film by an ALD process using the apparatus 10 of FIG. 1. The process can be performed using any apparatus capable of ALD of silicon dioxide at processing temperatures at or below about one hundred degrees Celsius (100° C.), such as a Hitachi Kokusai Electric Quixace II or a Tokyo Electric TEL IRAD or TELiNDY apparatus.

Initially, one or more substrates 100 are placed into the reaction chamber 11 (step 201). The substrates 100 can be semiconductor wafers having various structures formed thereon. For example, the substrates 100 can be a semiconductor substrate having a photoresist material (which can be patterned) on a top surface thereof. Alternatively, the substrates 100 can be a semiconductor substrate including heavily doped materials at the substrates' 100 surfaces. It should be appreciated that the method described herein can also be used to form silicon dioxide by ALD on any substrate surface that may outgas or contain residual materials that may promote defect formation.

In step 202, a pre-deposition pump and exhaust process is performed. During the pre-deposition pump and exhaust process, one or more cycles of pump and exhaust steps are performed. In a pump step 220, a purge gas is introduced, e.g., pumped via input component 20, into the reaction chamber 11. The purge gas can be nitrogen or any other inert gas. The pump step 220 is conducted from about 2 seconds to about 60 seconds and may be repeated (step 221) if desired. During the exhaust step 222, the purge gas is removed, e.g., exhausted via the exhaust component 30, from the reaction chamber 11. The exhaust step 22 is conducted from about 2 seconds to about 60 seconds and may be repeated (step 223) if desired. While step 202 is referred to as a pump and exhaust cycle, it should be understood that the pump step 220 and exhaust step 222 can be performed in any order. That is, a pump step 220 can be followed by exhaust step 222 or exhaust step 222 can be followed by pump step 220.

For the pre-deposition pump and exhaust process, each cycle 225 of pump step 220 and exhaust step 222 can be conducted between one and twenty (20) times, or more (step 224). A single pump and exhaust cycle 225 can include one or more pump steps and one or more exhaust steps. In one example, the pump and exhaust cycle 225 includes two (2) pump steps and one (1) exhaust step. During the pump and exhaust process (step 202), all apparatus lines 21, 31 are purged to maximize the removal of any residual materials (e.g., possible contaminants) present in the reaction chamber 11 or which could be introduced into the reaction chamber 11 during a subsequent processing step.

The pre-deposition pump and exhaust process (step 202) can be conducted while maintaining the substrate at a temperature at or below about one hundred degrees Celsius (100° C.) or between about one hundred degrees Celsius (100° C.) and about twenty degrees Celsius (20° C.). In one example the pre-deposition pump and purge process (step 202) can be conducted at a temperature at or below about seventy five degrees Celsius (75° C.), at or below about sixty five degrees Celsius (65° C.), or at or below about fifty five degrees Celsius (55° C.). Additionally, during all times after the substrates 100 are placed in the reaction chamber and prior to the deposition process (step 203), the substrates 100 can be maintained at a temperature at or below about seventy five degrees Celsius (75° C.), at or below about sixty five degrees Celsius (65° C.), or at or below about fifty five degrees Celsius (55° C.).

The temperature of the substrates 100 prior to the deposition process (step 203) can be maintained at or near the desired temperature for deposition to reduce the time needed to stabilize the temperature of the substrates 100 for the deposition process (step 203).

As the temperatures at which the substrate(s) are maintained during the pump and exhaust process (step 202) and the deposition process (step 203, described below) decrease, the number of pump and exhaust cycles 225 can be increased. Further, as the temperatures at which the substrate(s) is maintained during the pump and exhaust process (step 202) and the deposition process (step 203, described below) decrease, the time for each pump step 220 and exhaust step 222 can be increased.

In step 203, the deposition process is conducted to form the silicon dioxide film. The silicon dioxide film can be formed as desired by any known ALD process. Silicon precursors useful for depositing silicon-containing materials include silanes, alkylsilanes, aminosilanes, alkylaminosilanes, silanols, alkoxy silanes and hexachlorodisilane (HCD). The oxidizing component can include oxygen, hydrogen peroxide, nitrogen oxides and water, among others.

The deposition process can occur while maintaining the substrate at any suitable temperature. In one example, the deposition process is conducted while maintaining the substrate at or below about one hundred degrees Celsius (100° C.) or between about one hundred degrees Celsius (100° C.) and about twenty degrees Celsius (20° C.). In another example the pre-deposition pump and purge process (step 202) can be conducted at a temperature at or below about seventy five degrees Celsius (75° C.). In another example, the deposition process (step 203) is conducted while maintaining the substrate or below about sixty five degrees Celsius (65° C.). In a further example, the deposition process (step 203) is conducted while maintaining the substrate or below about fifty five degrees Celsius (55° C.).

By including the pre-deposition pump and exhaust process (step 202), the silicon dioxide film can be formed using lower processing temperatures (e.g., below about seventy five degrees Celsius (75° C.) lower standby temperatures to achieve increased rate of formation, reduced resist deformation and low defect formation.

### EXAMPLES

Table 1 shows the defects in silicon oxide films formed by a same deposition method using HCD and water at various processing and standby temperatures and with and without the pre-deposition pump and exhaust process described herein. The exhaust gas used was nitrogen and each pump and exhaust cycle included two pump steps 220 and one exhaust step 222.

As can be seen in Table 1, the pre-deposition pump and exhaust process significantly decreases the number of defects observed in the silicon dioxide film formed at lower processing temperatures with lower standby temperatures.

TABLE 1

| | | | Number of Pre- | |
|---|---|---|---|---|
| | Deposition | Standby | deposition | |
| | Temp | Temp | pump/exhaust | Number of |
| Parameter | (° C.) | (° C.) | cycles | Defects |
| Example 1 | 65 | 65 | 0 | 200000 |
| Example 2 | 65 | 65 | 0 | 121178 |
| Example 3 | 65 | 65 | 0 | 200000 |
| Example 4 | 65 | 75 | 0 | 2579 |
| Example 5 | 65 | 75 | 0 | 926 |
| Example 6 | 65 | 65 | 4 | 569 |
| Example 7 | 65 | 65 | 4 | 641 |
| Example 8 | 65 | 65 | 8 | 817 |
| Example 9 | 65 | 65 | 8 | 500 |
| Example 10 | 65 | 65 | 16 | 589 |
| Example 11 | 65 | 65 | 16 | 1459 |

While disclosed embodiments have been described in detail, it should be readily understood that the claimed invention is not limited to the disclosed embodiments. Rather the disclosed embodiments can be modified to incorporate any number of variations, alterations, substitutions or equivalent arrangements not heretofore described.

What is claimed as new and desired to be protected by Letters Patent of the United States is:

1. A method of forming a silicon dioxide material, the method comprising:
prior to forming the silicon oxide material:
introducing a purge gas into a reaction chamber, and
removing the purge gas from the reaction chamber; and
forming the silicon oxide material on a surface of the substrate.

2. The method of claim 1, wherein introducing the purge gas into the reaction chamber comprises pumping the purge gas into lines of the apparatus connected to the reaction chamber.

3. The method of claim 2, wherein removing the purge gas from the reaction chamber comprises exhausting the purge gas from the lines of the apparatus connected to the reaction chamber.

4. The method of claim 1, wherein the substrate is maintained at a temperature at or below about 75° C. during one or more of the introducing, removing and forming acts.

5. The method of claim 1, wherein the substrate is maintained at a temperature at or below about 75° C. during one or more introducing, removing and forming acts.

6. The method of claim 1, wherein the substrate is maintained at a temperature at or below about 65° C. during one or more introducing, removing and forming acts.

7. The method of claim 1, wherein the substrate is maintained at a temperature at or below about 55° C. during the introducing, removing and forming acts.

8. The method of claim 4, wherein the substrate is maintained at a temperature at or below about 75° C. during the forming acts.

9. The method of claim 4, wherein the substrate is maintained at a temperature at or below about 100° C. during the depositing step.

10. The method of claim 1, wherein the substrate is maintained at about a same temperature during the at least one pump and purge cycle and the forming step.

11. The method of claim 10, wherein the substrate is maintained is at or below about 65° C.

12. The method of claim 1, wherein the acts of introducing and removing are repeated.

13. A method of forming a silicon dioxide material, the method comprising:
prior to forming the silicon oxide material:
pumping a purge gas into a reaction chamber and one or more lines connected to the reaction chamber,
exhausting the purge gas from the reaction chamber and the one or more lines connected to the reaction chamber;
maintaining the substrate at a temperature at or below about 100° C. prior to forming the silicon oxide material;
forming the silicon oxide material by atomic layer deposition on a surface of the substrate; and
maintaining the substrate at a temperature at or below about 100° C. during the forming act.

14. The method of claim 13, wherein the substrate is maintained at about a same temperature prior to forming the silicon oxide material and during the forming act.

15. The method of claim 14, wherein the temperature is at or below about 65° C.

16. The method of claim 14, wherein the temperature is at or below about 55° C.

17. The method of claim 13, wherein the silicon oxide is formed in contact with a resist material.

18. The method of claim 13, wherein the pumping and exhausting are performed to remove residual material from the reaction chamber and the one or more lines.

19. The method of claim 13, wherein the purge gas comprises nitrogen.

20. The method of claim 13, wherein forming the silicon oxide material comprises forming the silicon oxide material using hexachlorodisilane and water.

21. A method of preparing a substrate for an atomic layer deposition process, the method comprising:
prior to forming a material by an atomic layer deposition process:
pumping a purge gas into a reaction chamber, and
exhausting the purge gas from the reaction chamber.

22. The method of claim 21, wherein c pumping the purge gas into the reaction chamber comprises pumping the purge gas into lines of the apparatus connected to the reaction chamber to remove residual material from the reaction chamber and one or more lines.

23. The method of claim 21, wherein exhausting the purge gas from the reaction chamber comprises exhausting the purge gas from lines of the apparatus connected to the reaction chamber to remove residual material from the reaction chamber and one or more lines.

24. The method of claim 21, wherein the substrate is maintained at a temperature at or below about 75° C. during the pumping and exhausting acts.

25. The method of claim 21, wherein the substrate is maintained at a temperature at or below about 65° C. during the pumping and exhausting acts.

26. The method of claim 21, wherein the substrate is maintained at a temperature at or below about 55° C. during the pumping and exhausting acts.

27. The method of claim 21, wherein pumping and exhausting comprises conducting between 1 and 20 pump and exhaust cycles.

28. The method of claim 21, wherein pumping comprises pumping the purge gas for a time between about 2 second and about 60 seconds and wherein exhausting comprises exhausting the purge gas for a time between about 2 second and about 60 seconds.
